(19) United States
(12) Patent Application Publication
(10) Pub. No.: US 2026/0330077 A1
(43) Pub. Date: Oct. 22, 2026

(54) SYSTEM AND METHOD FOR GEOMETRIC RECONSTRUCTION

(71) Applicant: Vinci4D.ai. Inc., Palo Alto, CA (US)

(72) Inventors: Sheik Dawood Beer Mohideen, Palo Alto, CA (US); Hardik Kabaria, Palo Alto, CA (US)

(73) Assignee: Vinci4D.ai. Inc., Palo Alto, CA (US)

(21) Appl. No.: 19/654,777

(22) Filed: Apr. 22, 2026

Related U.S. Application Data
(60) Provisional application No. 63/792,746, filed on Apr. 22, 2025.

(51) Int. Cl. G06F 30/12; G06F 30/20

(52) U.S. Cl. CPC G06F 30/12; G06F 30/20

(57) ABSTRACT

The method can include receiving an object representation; determining a geometry from the object representation; determining a set of anchor points from the geometry; determining a final geometry from the set of anchor points; and optionally updating the final geometry. The method functions to enable precise, accurate geometry editing. In variants, this can enable multiple versions of a geometry to be rapidly generated.

### CROSS-REFERENCE TO RELATED APPLICATIONS

This application claims the benefit of US Provisional Application number 63/792,746 filed 22-APR-2025, which is incorporated in its entirety by this reference.

### TECHNICAL FIELD

This invention relates generally to the modelling field, and more specifically to a new and useful method for generating and editing object geometries in the 3D modelling field.

### BRIEF DESCRIPTION OF THE FIGURES

FIG. 1 is a schematic representation of a variant of the method.

FIG. 2 is a schematic representation of a variant of determining a final geometry.

FIG. 3 is a schematic representation of a variant of editing anchor points to generate an updated final geometry.

FIG. 4 is a schematic representation of a variant of encoding geometric information to generate a final geometry.

FIG. 5 is a schematic representation of a variant of updating a geometry.

FIG. 6 is an illustrative example of: generating a model from an uploaded image, editing the model, and generating a new model based on the edits.

FIG. 7 is an illustrative example of precise, localized edits (e.g., changing the curvature of a phone bezel).

FIG. 8 is an illustrative example of a variant of the system.

### DETAILED DESCRIPTION OF THE INVENTION

The following description of the embodiments of the invention is not intended to limit the invention to these embodiments, but rather to enable any person skilled in the art to make and use this invention.

### 1. Overview

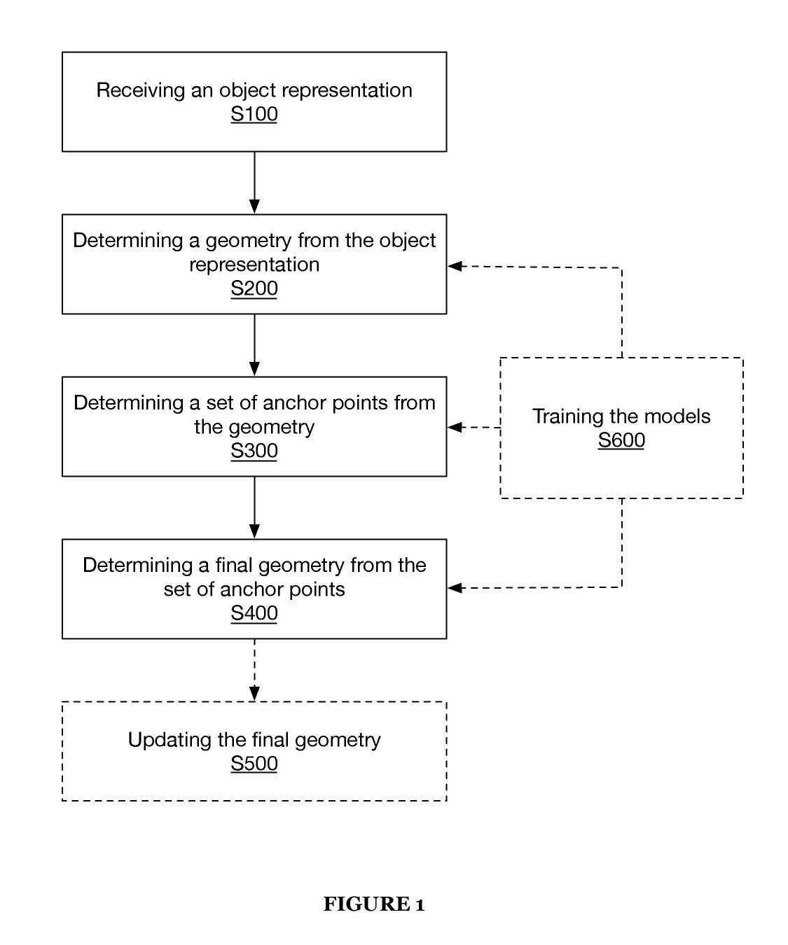

As shown in FIG. 1, variants of the method can include: receiving an object representation S100; determining a geometry from the object representation S200; determining a set of anchor points from the geometry S300; determining a final geometry from the set of anchor points S400; and optionally updating the final geometry S500. The method functions to enable precise, accurate geometry editing of an object. In variants, this can enable multiple versions of a geometry (e.g., different resolutions, modified geometries, etc.) and/or multiple different geometric objects to be rapidly generated.

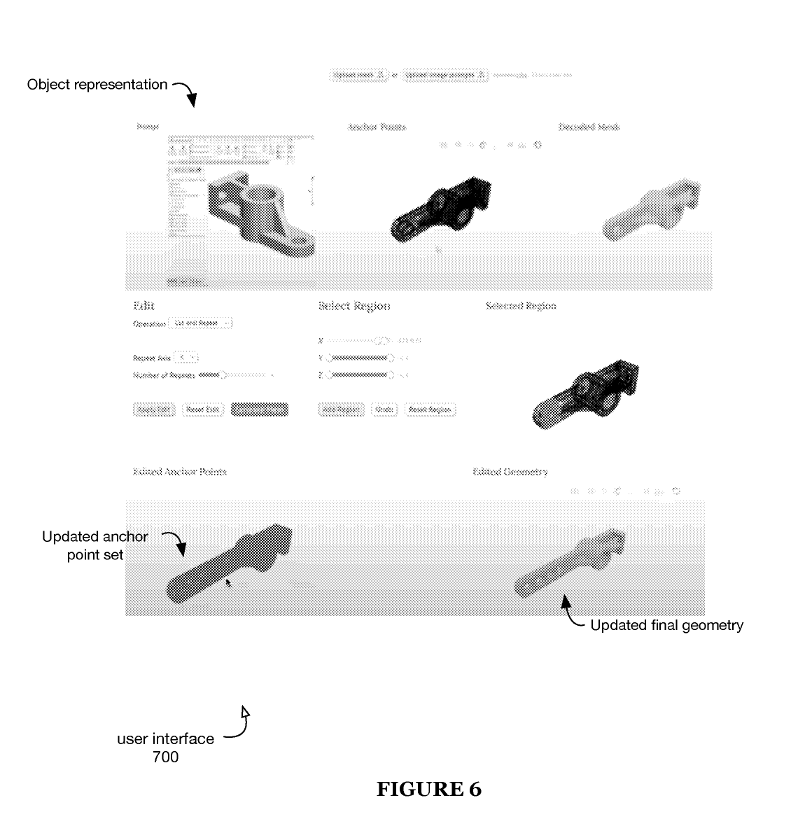

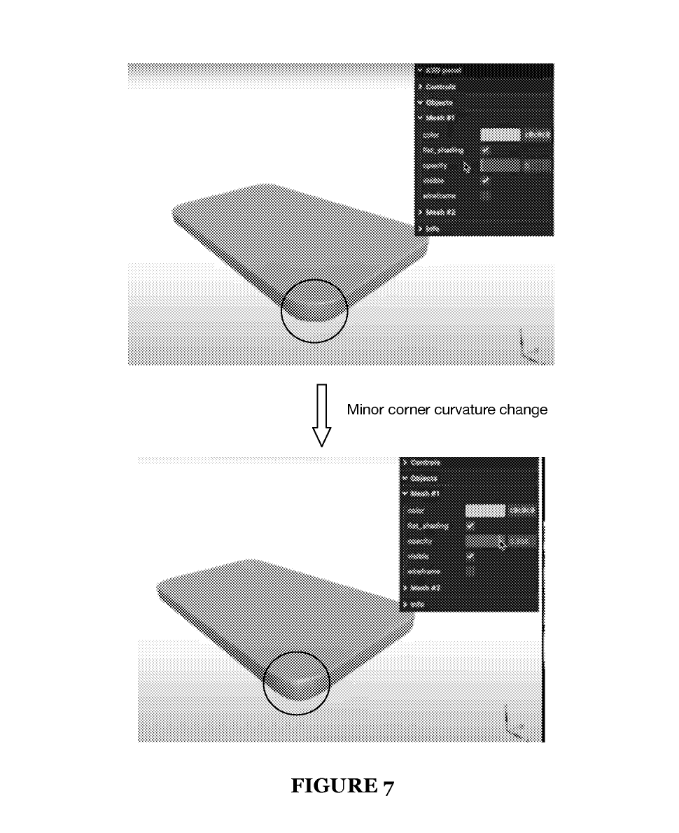

In an illustrative example, the method can include: optionally receiving an object representation (e.g., an image), determining a geometry (e.g., from the object representation), determining anchor points for the geometry, determining anchor latents encoding local geometric information for each anchor point from the geometry, determining a global representation based on the anchor latents (e.g., using a transformer), querying the global representation for spatial values (e.g. occupancy values, SDFs, etc.) at each of a set of sampling positions, and determining a final geometry from the spatial values using 3D reconstruction methods. In an example, determining the anchor latents can include: encoding small local geometric features into geometric latents for each of a set of positions (e.g., generating geometry-aware local adaptive (GALA) node latents), selecting a set of anchor points based on the geometry, mapping the geometric latents (e.g., GALA node latents) to the anchor points (e.g., to adjacent anchor points, etc.), and encoding the geometric information from the geometric latents into the anchor latents (e.g., by passing the anchor points as queries and the GALA node latents as keys and values into an encoder). The method can also include updating the final geometry, which can be performed by: determining new positions for one or more anchor points; maintaining the anchor latents associated with each adjusted anchor point (e.g., such that the anchor point is located in a new position in space, but remains associated with an anchor latent that encodes the old local geometric information); optionally determining an updated global representation using the new anchor point positions and the old anchor latents; querying the updated global representation to determine updated spatial values for each of the set of sampling positions; and generating an updated geometry based on the updated spatial values. In examples, this can enable users to make precise, local changes to the geometry while maintaining the geometry of the remainder of the object (e.g., example shown in FIG. 7); copy and paste geometric features (e.g., example shown in FIG. 6); remove features from the geometry (e.g., creating a hole through a solid object); and/or otherwise edit the geometry in real- or near-real time.

However, the method can be otherwise performed.

### 2. Technical advantages

Variants of the technology can confer one or more advantages over conventional technologies.

First, variants of the technology can enable geometries to be dynamically editable, providing users with the ability to modify and manipulate geometric structures in real-time. By implementing a flexible representation framework, the technology can allow for interactive adjustments to complex three-dimensional models without requiring complete regeneration of the underlying data structures. For example, the method can encode the geometry into latent space (e.g., as a set of embeddings, as a set of feature vectors, etc.), and associate geometry anchor points with latent vectors encoding localized geometries surrounding the respective anchor points. The geometry can be modified by moving the anchor points, wherein an updated geometry can be regenerated from the respective latent vectors (e.g., the respective local geometries) and the new anchor point locations. This dynamic editability can significantly enhance workflow efficiency in fields such as architectural design, industrial modeling, and virtual environment creation, where iterative refinement is a common requirement.

Second, variants of the technology can generate accurate, high-resolution meshes that faithfully represent complex geometrical structures with minimal approximation errors. The technology can employ advanced discretization techniques (e.g., locally adaptive grids, wavelet-space transforms, etc.) to create detailed surface representations that capture fine features and maintain geometric fidelity.

Third, variants of the technology can be computationally efficient and minimize computational redundancy by employing optimized algorithms and data structures. By strategically allocating computational resources based on geometric complexity and relevance, the technology can reduce processing overhead and memory requirements compared to conventional approaches. For example, the technology can implement spatial partitioning schemes (e.g., octrees, k-d trees, etc.) to focus computational efforts on regions of interest while using simplified representations for less critical areas. Furthermore, variants of the technology can generate new geometries by reusing the previously-computed anchor latents (e.g., latents encoding local geometric features) for each anchor point and simply updating the anchor point positions, instead of re-encoding the new geometry. This efficiency can enable real-time performance on resource-constrained platforms and facilitate processing larger, more complex datasets than would otherwise be possible with traditional methods, thereby extending the practical applicability of geometric processing across diverse computing environments.

However, further advantages can be provided by the system and method disclosed herein.

### 3. Method

As shown in FIG. 1, the method can include receiving an object representation S100; determining a geometry from the object representation S200; determining a set of anchor points from the geometry S300; determining a final geometry from the set of anchor points S400; optionally updating the final geometry S500; and optionally training the models S600. The method functions to determine an editable geometry based on an object representation. The method can be performed by a computing system and/or any other system. All or portions of the method can be performed one or more times for any object representation. The method can generate the geometry of an object (e.g., mesh, etc.), anchor points, latents encoding geometric and/or positional information, a global representation of an object, and/or any other data representation.

The method can be performed using a set of models. The models can use classical or traditional approaches, machine learning approaches, and/or other approaches. The models can include encoders, transformers, diffusion models, decoders, rulesets, neural networks (e.g., MLPs, DNNs, CNNs, RNNs, etc.), hybrid architectures, and/or any other model architectures. The models can include a set of attention layers (e.g., self-attention layers, cross-attention layers, sliced attention, flash attention, local attention, multi-head attention, etc.), feedforward layers, convolutional layers, recurrent layers, positional encoding layers, and/or any other layers. The set of models can include a sampling module (e.g., anchor point selection model) that selects anchor points based on the object geometry, a local geometry encoder that generates the local geometric latents based on the geometry, a controllable latent model (e.g., an encoder, an attention-based architecture, a transformer, etc.) that generates controllable anchor latents based on the local geometric latents adjacent each anchor point (e.g., using a query-key-value (QKV) mechanism), a global representation model (e.g., transformer, set of cross-attention layers, etc.) that encodes the global representation for the geometry based on the set of controllable anchor latents, a query point selection model that selects query points in arbitrary space, a spatial value model (e.g., decoder, attention-based architecture, transformer, etc.) that determines spatial values for each sampling point based on the global representation (e.g., using a QKV mechanism), a geometry reconstruction model that reconstructs a mesh from the set of spatial values, and/or any other models. In examples, the local geometry encoder can include: a local coordinate system (e.g., geometry-aware local adaptive grid (GALA) model, PointNet, Frame Fields, SplineCNN, etc.), spectral embeddings (e.g., ShapeNet, MeshCNN, graph Laplacians, etc.), geodesic-based embeddings (e.g., geodesic CNNs, heat kernel signatures, etc.), and/or other architectures.

Receiving an object representation S100 functions to determine an object or object representation from which a geometry will be determined. The object representation can represent an object, where the object can be a physical object, simulated object, object design, and/or any other object. The object representation can be a set of images (e.g., monocular image, stereo image, depth image, etc.), video, CAD (computer-aided design) file, text, point cloud, mesh (e.g., polygonal mesh), and/or any other representation. The object representation can be manually generated by a user, generated using sensors (e.g. cameras, LiDAR, etc.), received from a file, and/or otherwise determined. In an example, the object representation can be an image or set of images of an object. In a second example, the object representation can be a CAD file, which defines faces, edges, vertices, primitive shapes, parametric equations, and/or any other attributes of an object. In another example, the object representation can be text describing the shape and geometry of an object. In other examples, the object representation can be a point cloud. However, the object representation can be in any format.

However, receiving an object representation S100 may be otherwise configured.

Determining a geometry from the object representation S200 functions to determine an initial geometric representation of an object from the object representation. The geometry can be the 3D shape of an object. The geometry can be a mesh, a grid, a set of voxels, set of points, a set of surfaces, and/or any other geometric representation. Determining a geometry from the object representation S200 can be performed manually, using models, and/or any other method.

In a first variant, a geometry can be determined from an image. Determining a geometry from an image can be performed using machine learning models, neural networks, photogrammetric methods (e.g. Structure from Motion, Shape from Shading, etc.), manual determination, parametric modeling, and/or any other methods. In a second variant, a geometry can be determined from the CAD file. A mesh can be extracted from a CAD file using different algorithms and methods like tessellation, adaptive meshing, marching cubes, and/or any other algorithms and methods. In a third variant, the object representation is text, wherein a geometry can be determined from the text. Determining a geometry from text can be performed using machine learning models (e.g., LLMs, generative AI, text-to-3D models, diffusion models, etc.), manual determination, parametric modeling, and/or any other method.

However, determining a geometry from the object representation S200 can be and/or otherwise performed.

Determining a set of anchor points from the geometry S300 functions to determine a set of points that is representative of the geometry. Determining a set of anchor points from the geometry S300 can be performed using a sampling module (e.g., anchor point selection model), and/or any other model. The resultant set of anchor points can be uniformly distributed over the geometry, nonuniformly distributed over the geometry (e.g., concentrated in regions with high curvature or high geometric complexity, diffuse in regions with low curvature or low geometric complexity, etc.), adaptively sampled across the geometry, and/or otherwise distributed. S300 can be performed using uniform sampling, adaptive sampling, multi-resolution sampling, sampling based on a geometric or design property (e.g., curvature, density, surface normals, error metrics, reconstruction uncertainty, distance from a reference location, learned feature importance, etc.), probabilistic sampling, importance sampling, stratified sampling, Poisson sampling, grid sampling, farthest point sampling, blue-noise sampling, Markov chain Monte Carlo sampling, rejection sampling, low-discrepancy sequence sampling, quasi-random sampling, random sampling, sampling based on a ruleset, and/or any other method.

In a first variant, determining a set of anchor points from the geometry S300 can involve uniform sampling. Uniform sampling can be a sampling method in which every point of the geometry has an equal probability of being selected as an anchor point. The uniform sampling can be performed in any suitable method. The uniform sampling can result in equally spaced anchor points. The uniform sampling can be used to determine a qualitatively unbiased representation and for thoroughly sampling the domain.

In a second variant, determining a set of anchor points from the geometry S300 can involve edge sampling. Edge sampling can be a sampling method that can prioritize boundaries and/or edges of the mesh. In a first variant, edge sampling can include edge length sampling, wherein every edge of the geometry is uniformly sampled at a rate of "n" samples per unit of length. However, edge length sampling can be otherwise performed. In a second variant, edge sampling can include angle-based edge sampling, wherein anchor points are biased based on angular positioning. In an example, angle-based edge sampling can include computing the angle of neighboring vectors of the mesh and biasing towards sampling regions in which neighboring vectors form an angle less than and/or greater than some value (e.g., 10°, 20°, 30°, 40°, 45°, 50°, 60°, 70°, 80°, 90°, 100°, 120°, 130°, 140°, 150°, 160°, 170°, 180°, or any value therebetween). However, angle-based edge sampling can be otherwise performed. Edge sampling can be performed in any other suitable manner.

In a third variant, determining a set of anchor points from the geometry S300 can use blue noise sampling. Blue noise sampling can be a sampling method which can achieve a distribution of anchor points that are evenly distributed but have minimal correlation. The blue noise sampling can minimize clustering, low-frequency patterns, and/or grid-like artifacts. Blue noise sampling can be performed using a Poisson disk sampling algorithm, Lloyd's relaxation method, rejection sampling with frequency filtering, and/or any other sampling methods.

In a variant, the anchor points can be measured. For example, a laser scanner, LiDAR, structured light scanner, time-of-flight camera, photogrammetry camera system, stereo camera, probe arm, coordinate measuring machine, and/or any other suitable measuring device, can be used to measure the position of a set of anchor points for a physical geometry.

In another variant, the anchor points can be determined using a machine learning model. In variants, the anchor points can be determined using a set of rules, policies, and/or heuristics. The rules, heuristics, and/or policies can be handcrafted, manually determined, learned, and/or otherwise determined. In an example, a policy can define different sampling resolutions based on different geometry properties and/or features.

However, determining a set of anchor points from the geometry S300 may be otherwise configured.

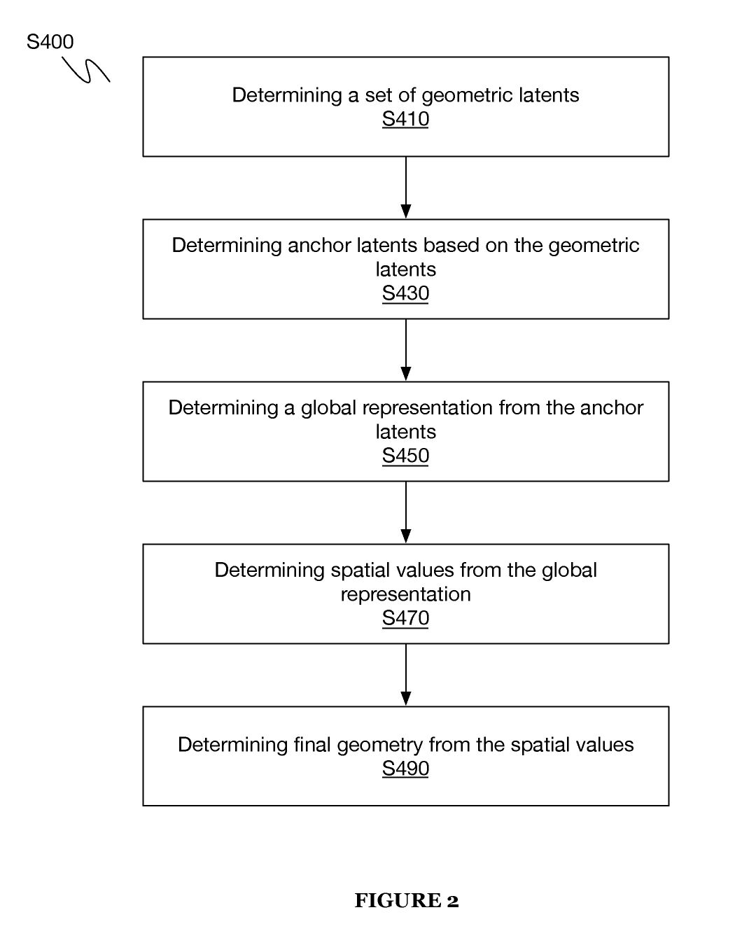

Determining a final geometry from the set of anchor points S400 functions to generate a representation of the geometry, as shown for example in FIG. 2. The final geometry can encode more information than the original geometry (e.g., equivalent or higher resolution than the original geometry, and/or any other information), have more versatility than the originally determined geometry, and/or be otherwise related to the original geometry. The final geometry can be a high-quality mesh, hull, point cloud, and/or any other object representation. In variants (as shown for example in FIG. 2), determining a final geometry from the set of anchor points S400 can include determining a set of local geometric latents S410; determining controllable anchor latents based on the local geometric latents S430; determining a global representation from the controllable anchor latents S450; determining spatial values from the global representation S470; and determining a final geometry from the spatial values S490.

Determining a set of local geometric latents S410 functions to encode local geometric information for each of a set of nodes. The nodes can be locations on the geometry, locations in a virtual space encompassing the geometry, and/or any other set of positions. The nodes are preferably different from the anchor points (e.g., be a different set of points, have a different spatial distribution, etc.), but can alternatively be the anchor points. In variants, the nodes can sampled at a higher resolution than the anchor points, however can alternatively be sampled at a lower resolution or the same resolution. Determining a set of local geometric latents S410 can be performed using the local geometry encoder and/or any other encoder. The set of local geometric latents can encode the geometry in higher fidelity than the anchor points, encode the geometry using a different representation from the anchor points, or can alternatively encode the geometry in a similar manner to the anchor point latents. In an example, determining a set of local geometric latents S410 can include determining an adaptive grid based on the local geometry (e.g., using PCA of the surface normals, etc.), optionally include embedding the grid as a set of vectors (e.g., including grid cell position, scale, geometry values, quaternion, geometric field values, etc.), include embedding the grid into a preliminary geometric latent space (e.g., using an encoder, set of diffusion models, graph diffusion models, and/or any other models). In variants, each node (e.g., grid cell) is associated with a preliminary geometric latent. Alternatively, the local geometric latents for each of the set of nodes can be determined using PointNet, CNNs, ShapeNet, and/or any other module and/or model.

Determining a set of local geometric latents S410 can include determining a grid, determining a field representation of the geometry, encoding geometric information, and/or any other suitable steps. The grid can be uniform, anisotropic, locally-adaptive (e.g., dynamically adjusted to match the curvature and topology of the geometry), and/or any other type of grid. The grid can split a space into nodes and/or voxels. However, the geometry can be otherwise discretized. A field-based representation can include local geometric values (e.g., for a discretized space). The local geometric values can include or be represented by signed distance function, distance function, gradients (e.g., of the density, normal vector, curvature, tangent vectors, distance functions, spatial coordinates, etc.), density, and/or other measurement of the local geometry adjacent each node. The local geometric values can be determined for the nodes (e.g., grid nodes, grid voxels, etc.) and/or any spatial positions of the geometry and/or geometric representation. In an example, the local geometric values can represent a discretized field.

Encoding geometric information can include passing the local geometric values through a set of attention layers (e.g., a set of self-attention layers, etc.), an encoder, and/or any other suitable model. Encoding geometric information can alternatively include transforming geometric values into a different domain and/or basis, such as a frequency-space (e.g. Fourier transform, Laplace transform, etc.), scale-space or spectral-space (e.g., wavelet transform, Hilbert-Huang transform, etc.), latent space, or any other space. The geometric information can be structured in hierarchical data structures (e.g. Octree, Quadtree, B-tree, k-d tree, R-tree, etc.). In a variant, local geometric values for multiple grid sizes can be determined and structured in an octree for capturing multiple resolutions of the geometry. In another variant, the geometric values are transformed into frequency space, resulting in decoupled resolution-specific descriptions of the geometry (e.g., which can be stored in an octree). However, geometric information can be otherwise encoded, transformed, or organized. The local geometric latents can be treated as a key-value structure, wherein the location of the node is a key and the local geometric latents are values. However, the local geometric latents can be otherwise structured.

However, determining a set of local geometric latents S410 may be otherwise configured.

Determining controllable anchor latents based on the local geometric latents S430 functions to encode the local geometry surrounding each anchor point. Determining controllable anchor latents based on the local geometric latents S430 can be performed using a controllable anchor latent encoder, clustering module, and/or any other components.

Determining controllable anchor latents based on the local geometric latents S430 can include mapping the local geometric latents to an anchor point. Mapping the local geometric latents to an anchor point can function to determine the local geometric latents for the geometric nodes proximal each anchor point. Mapping the local geometric latents to an anchor point can be performed using a clustering module and/or any other suitable module. A single local geometric latent or a plurality and/or cluster of local geometric latents can be mapped to an anchor point. A local geometric latent can be assigned to one or multiple anchor points. The local geometric latents can be assigned to anchor points based on: spatial distance (e.g., the local geometric latent is assigned to anchor points based on nearest neighbors in space), a rule set, a distance within latent feature space, and/or otherwise assigned.

When multiple local geometric latents are associated with an anchor point, the local geometric latents can be weighted, such that each local geometric latent has a different weight coefficient for different anchor points (e.g., based on the relative proximity, etc.). The weights can be determined based on spatial proximity, heuristics, learned policy, an importance metric, and/or any other suitable method. In an example, local geometry latents that are closer to the anchor point can have a higher weight. In an example, local geometry latents that are associated with specific geometric features can have a higher weight. However, the weights can be otherwise defined.

The mapping of the local geometric latents to an anchor point can generate non-overlapping clusters, overlapping clusters, hierarchical clusters, and/or any other suitable clusters. In a first variant, each local geometric latent can be assigned to one anchor point. In a second variant, a local geometric latent can be assigned to a plurality of anchor points (e.g., based on a threshold spatial proximity). In a third variant, every local geometric latent can be assigned to every anchor point but with a corresponding weight (e.g., by its proximity, etc.). However, the local geometric latents can be otherwise mapped and/or clustered.

Determining controllable anchor latents based on the local geometric latents S430 can include encoding the local geometric latents mapped to each anchor point to determine the controllable anchor latents. Encoding the local geometric latents to the corresponding anchor point can be performed using an encoder (e.g., wherein the anchor points are used as queries, and the local geometric latents are used as keys and values). In an example, determining controllable anchor latents based on the local geometric latents S430 can include querying the local geometric latents using the anchor points, wherein each anchor point is used as a query and the local geometric latents are used as keys and values (e.g., wherein the local geometric node position is used as the key and the local geometric latent is used as the value). In an example, determining a controllable anchor latent can include passing all local geometric latents associated with an anchor through an encoding module. The encoding module can determine a latent vector and/or other data representation that describes all local geometric latents. In this variant, a controllable anchor latent can encode the surrounding geometric information. In variants, this can allow each anchor point to only pay attention to its associated local geometric latents. In variants, the set of local geometric latents associated with each anchor point can optionally be transformed into a vector representation (e.g., using a wavelet transform, Fourier transform, etc.) before querying.

However, determining controllable anchor latents based on the local geometric latents S430 may be otherwise configured.

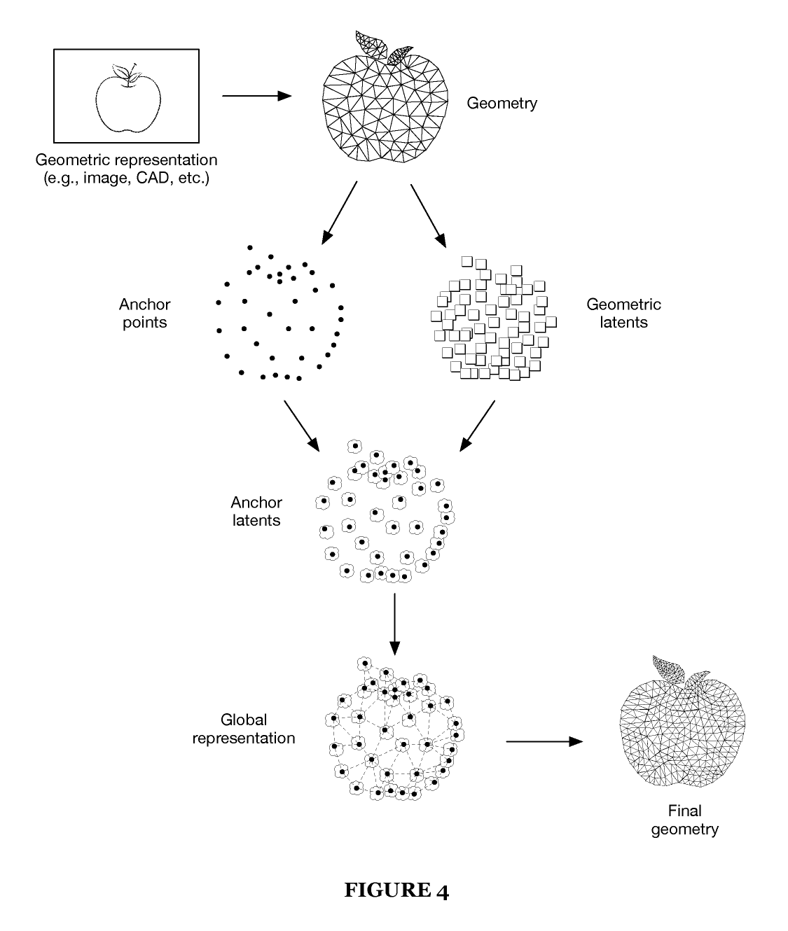

Determining a global representation from the controllable anchor latents S450 functions to determine global context of the geometry. The global representation can be a high-level representation of the geometry. In an example, the global representation can include a set of global latents and/or latent feature vector associated with the controllable anchor latents, wherein the global latents encode the entire geometry. Determining a global representation from the controllable anchor latents S450 can be performed using the global representation generator and/or any other suitable components. In variants, the global representation model can have an encoder-decoder architecture (e.g. UNet Seq2Seq, and/or any other architectures), where the global representation is determined using the encoder of the architecture. The global representation can encode information about the relationships between controllable anchor latents, as shown for example in FIG. 4.

In a first example, all controllable anchor latents and the associated anchor points are fed as input to a transformer or set of cross-attention and/or self-attentions layers, such that each anchor point learns the geometry of the other anchor points and forms the global representation. In variants, the last hidden tokens of the global representation model can function as a condensed global summary of the geometric information. In a second example, the set of controllable anchor latents can be passed as input to a machine learning model (e.g., encoder, etc.). The machine learning model can output a tensor, matrix, feature map, and/or any other representation that represents the connection and/or relationship between all controllable anchor latents of the geometry. In a third example, a global representation can be an aggregation of geometric information.

However, determining a global representation from the controllable anchor latents S450 can be otherwise performed.

Determining spatial values from the global representation S470 functions to extract spatial geometry from the global representation. The spatial values can include: occupancy values (e.g., occupancy probabilities, binary occupancy values, etc.), densities, distance function, signed distance function, normals, gradients, curvatures, O-voxel parameters, classifications (e.g., interior, exterior, surface, etc.), neural representations, wavelet fields, O-voxel parameters, and/or any other spatial field representation. Determining spatial values from the global representation S470 can be performed using a spatial value decoder.

In a first variant, determining spatial values from the global representation S470 can include querying the global representation using a set of sampling and/or query points.

Determining spatial values from the global representation S470 can include querying the global representation using a set of sampling and/or query points. In variants, the query points can be evenly distributed throughout a virtual space, unevenly distributed throughout the virtual space, and/or otherwise distributed. In an example, the query points can be points on a grid. The query point resolution can be predetermined, manually selected (e.g., based on the desired resolution of the final geometry), iteratively determined (e.g., using coarse query points and iteratively densifying the query points; using an octree, etc.), and/or otherwise determined. The query points can be selected using a ruleset, uniform sampling, adaptive sampling, probabilistic sampling, grid sampling, Monte Carlo sampling, a ruleset, and/or any other sampling method. In some variants, the query points can be determined by the sampling module. The query points are preferably different from the anchor points, but can alternatively be the same. For example, the query points can have a higher resolution than the anchor points.

In variants, determining spatial values from the global representation S470 can include querying the global representation with the query points, wherein the query points are used as queries and the global representation (e.g., anchor points and associated global latents) are treated as keys and values. The query can output the occupancy value for the query point (e.g., whether the geometry occupies the query point to cooperatively generate a point cloud with occupancy values; etc.), the local geometry of the sampling point (e.g., decoded from the global latent associated with adjacent anchor points), an SDF (e.g., wherein the SDF-generating decoder is trained using a predetermined SDF target, such as an SDF for the initial geometry), and/or any other output. In an example, the query points (e.g., coordinates, XYZ positions, etc.) are passed as queries against the global representation's key-value pairs to determine occupancy values. The output from this operation can be processed through an MLP to generate the final occupancy value at the queried location (e.g., the sampling point).

For example, determining spatial values from the global representation can include passing the global representation and the set of query points through a decoder and/or any other model. The model and/or decoder can output spatial value. Examples of spatial values can include density, occupancy, probability of occupancy, signed distance, gradients, and/or any other geometric field value.

In a second variant, determining spatial values from the global representation S470 can include decoding the global representation into spatial values using a machine learning model. The machine learning model can be a decoder. In an example, the decoder can be the decoder of an encoder-decoder model, where the encoder-decoder model can be trained end-to-end to predict the input geometry, given the input geometry. Additionally or alternatively, the decoder can be independently trained to predict the input geometry given the geometric representation. However, the decoder can be otherwise trained. In variants, the machine learning model (e.g., decoder can include a cross-attention and/or any other attention mechanism to determine the spatial values. The machine learning model can include machine learning models such as neural networks, multi-layer perceptron, graph neural networks, convolutional neural networks, transformers, recurrent neural networks, natural language processing models (e.g., Seq2seq, etc.), state space models (e.g., Mamba model, etc.) hybrid architectures, and/or any other suitable model.

In a third variant, determining spatial values from the global representation S470 can be performed using look-up methods. For example, in variants where the global representation is an aggregation of geometric information, the spatial values associated with the query points can be pulled from the global representation. However, the spatial values can be otherwise determined.

However, determining spatial values from the global representation S470 may be otherwise configured.

Determining a final geometry from the spatial values S490 functions to reconstruct the geometry. The final geometry is preferably a mesh, but can alternatively be a point cloud, voxel grid, neural representation, set of splines, and/or any other geometric representation. The final geometry can be associated with the anchor points (e.g., herein the anchor points are located at the original anchor point locations on the geometry), unassociated with the anchor points, associated with the controllable anchor latents, associated with the query points (e.g., from S470, etc.) and/or otherwise associated. Determining a final geometry from the spatial values S490 is preferably determined from the spatial value set (e.g., determined in S470), but can alternatively be determined from the geometric representation, controllable anchor latents, anchor points, and/or any other input.

The final geometry can be determined from: a set of occupancy values (e.g., an occupancy grid), set of SDF values, set of gradients, combination thereof and/or any other suitable set of spatial values. In a first example, an SDF can be calculated from the occupancy value. In variants, a calculated SDF (e.g., determined from occupancy values) and the SDF determined from the global representation are averaged, aggregated, and/or otherwise combined. A mesh can then be determined from the combined SDF. In a second example, different meshes can be determined from different spatial value modalities, wherein the meshes are averaged, aggregated, and/or otherwise consolidated. In a third example, the spatial gradients are integrated to determine a set of sign distance values, wherein a mesh is generated from the set of signed distance values.

The final geometry is preferably determined using a meshing algorithm, but can additionally and/or alternatively be otherwise determined. Examples of meshing algorithms that can be used can include marching cubes, dual contouring, Poisson surface reconstruction, Delaunay-based meshing, alpha shapes, advanced front meshing, grid-based surface extraction, surface net algorithms, implicit function thresholding, contour extraction, hybrid methods, and/or other meshing algorithms.

In a first variant, the final geometry can be determined from SDFs. In variants in which the spatial values are SDFs, the final geometry can be determined from 3D reconstruction methods. In a first example, determining the final geometry from SDFs can involve performing a marching cubes algorithm. In a second example, determining a final geometry from the spatial values S490 can include iterating over the voxels of the occupancy grid and triangulating the boundaries to determine edges based on the signed distance fields. In a third example, determining a final geometry from the spatial values S490 can include interpolating surfaces from the edges. In a fourth example, determining a final geometry from the spatial values S490 can include outputting a triangle mesh defining the vertices of the geometry. In a fifth example, determining of the final geometry from SDFs can include performing dual contouring.

In a first specific variant, determining a final geometry from an SDF can include identifying grid edges based on SDF, calculating intersection points, computing optimal vertex positions using least squares fitting, and/or outputting quads defined by the vertex points. In a second specific variant, determining a final geometry from an SDF can involve performing Poisson surface reconstruction. Performing Poisson surface reconstruction can include determining surface points based on SDF, estimating surface normals, solving the Poisson equation to estimate a continuous surface, and/or generating a triangle mesh from the estimated function. In a third specific variant, determining a final geometry from an SDF can involve performing Delaunay tetrahedralization. Performing Delaunay tetrahedralization can include converting the SDF into a set of points through sampling and using the Delaunay triangulation algorithm to form a 3D tetrahedral mesh. In a fourth specific variant, determining a final geometry from an SDF can include using the Alpha shape algorithm to extract the outer surface. However, the final geometry can be determined from SDF in any suitable method.

In variants, the final geometry can be determined from multiple spatial value types. In variants in which the spatial values include both SDF and occupancy values, the information can be combined to determine a mesh. However, a mesh can be determined from multiple spatial value types in any other suitable method.

In another variant, the final geometry can be determined from gradients. In variants in which gradients are determined, the gradients can be integrated to determine local geometric values associated with the gradients.

In variants, determining a final geometry from the spatial values S490 can include performing post-processing on the final geometry. The post-processing performed on the final geometry can include smoothing, filling holes, and/or gaps, enforcing continuity, refining topology, mesh simplification, edge sharpening, noise removal, and/or any other steps. The post-processing steps can include performing Laplacian smoothing, Taubin smoothing, bilateral surface filtering, curvature-based interpolation, constrained patch filling, vertex clustering, edge collapse, curvature-based sharpening, edge enhancement, statistical outlier removal, median filtering, machine-learning based post processing (e.g., based on learned policy, etc.), and/or any other suitable post-processing steps.

However, determining a final geometry from the spatial values S490 may be otherwise performed.

However, determining a final geometry from the set of anchor points S400 may be otherwise configured.

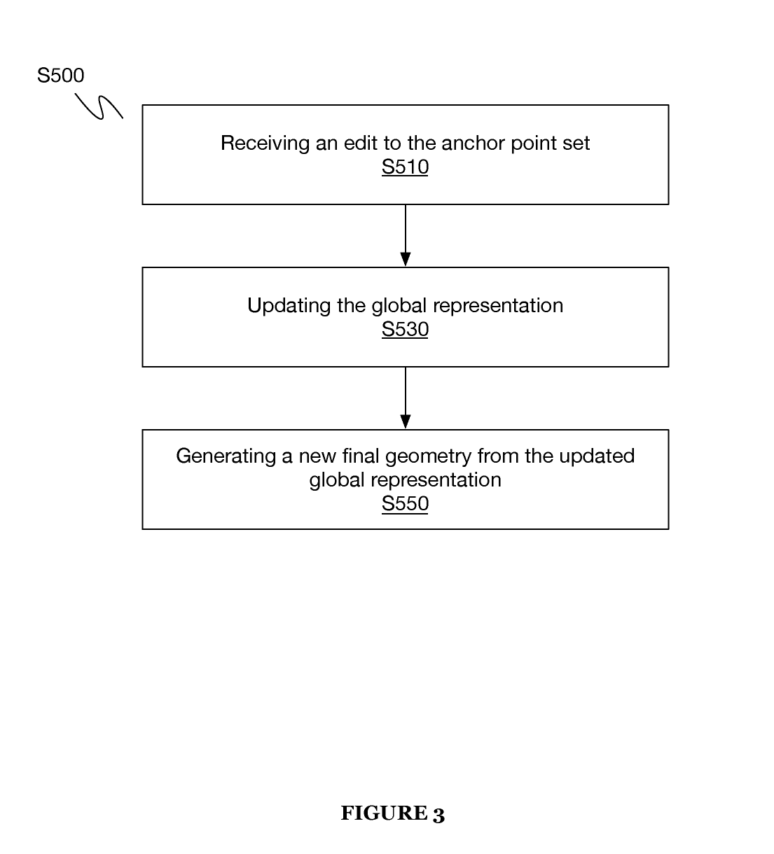

Updating the final geometry S500 functions to determine a new final geometry based on geometric transformations, as shown for example in FIG. 3. Updating the final geometry S500 can be repeated one or more times (e.g., for one or more transformations). S500 can be performed after a set of controllable anchor latents are determined, after a geometric representation is determined, or at any time during the method. In variants, updating the final geometry S500 includes receiving an edit to the controllable anchor latents S510; updating the global representation S530; and generating a new final geometry from the updated global representation S550.

Receiving an edit to the controllable anchor latents S510 functions to describe a desired change in the geometry. Receiving an edit to the controllable anchor latents S510 can include moving, adding, removing, perturbing, randomly reassigning, scaling, and/or otherwise modifying anchor points and/or controllable anchor latent. The edit can be received as a user input at a user interface displaying the set of anchor points, as a text prompt, as a voice input, as a target image, and/or in any other modality. In other variants, the edits can be determined algorithmically, based on learned policy, by a machine learning model and/or agent, and/or using any other suitable method. In variants, the edit can include editing the anchor points and/or editing the controllable anchor latents. For example, editing the position of an anchor point can change the position the controllable anchor latent is associated with. The modified anchor points preferably remain associated with the prior controllable anchor latents, but can additionally and/or alternatively remain associated with the global latents, be disassociated from the controllable anchor latents, disassociated from the global latents, and/or otherwise be associated with the predetermined latents.

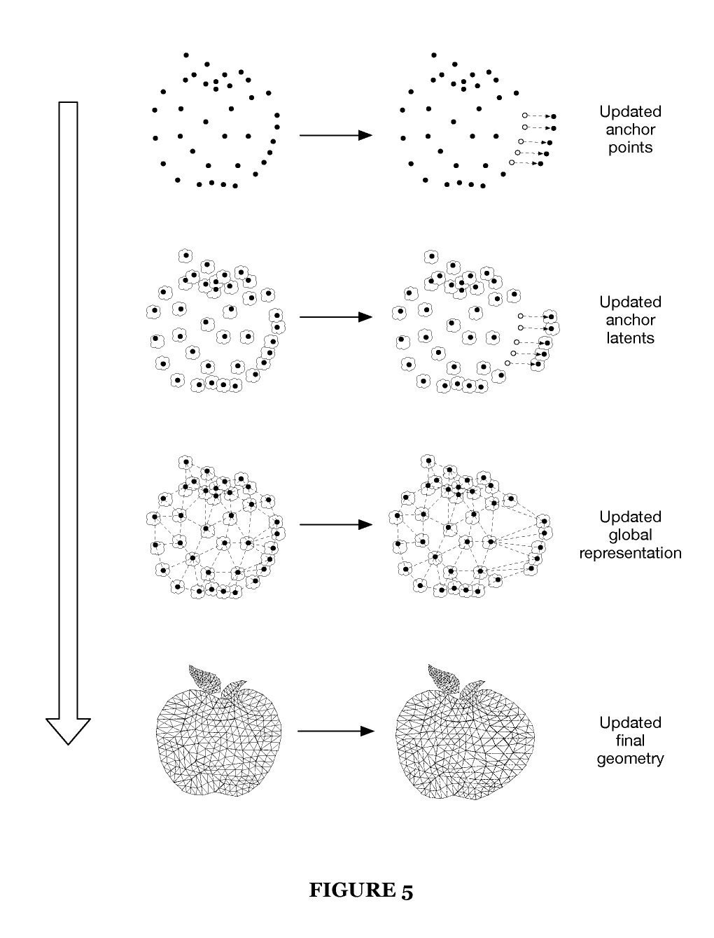

In a first variant, receiving an edit to the controllable anchor latents S510 can include relocating one or more controllable anchor latents. Relocating one or more controllable anchor latents can describe new positional coordinates of controllable anchor latents. In an example, changes to the geometry can include dragging, twisting, stretching, and/or otherwise deforming the geometry, resulting in new spatial positions for the anchor points, as shown in FIG. 5. The geometry deformations can affect all controllable anchor latents or a subset of the controllable anchor latents (e.g., the selected subset of anchor points). The new coordinates for the controllable anchor latents can be manually inputted, computed from mathematical transformations, determined using model editing software, or otherwise determined.

In a second variant, receiving an edit to the controllable anchor latents S510 can include adding new controllable anchor latents. New controllable anchor latents can be added to a set of positions within the virtual space encompassing the geometry. The set of positions can be: manually determined (e.g., copied and pasted), automatically determined (e.g., based on old and new anchor point similarity, predicted using a ML model, etc.), and/or otherwise determined. The new controllable anchor latents can be associated with predetermined latents (e.g., controllable anchor latents, global latents, etc.), be associated with a set of default latents, be associated with a new set of latents (e.g., determined using diffusion, flow matching, and/or any other methods), and/or otherwise determined. The new controllable anchor latents can be copied from the same geometry, copied from a different geometry, generated (e.g., using a diffusion model, etc.), and/or otherwise determined. In an example of the second variant, adding new controllable anchor latents can be used to add repeating features to the geometry. In an illustrative example, receiving an edit to the controllable anchor latents S510 can be used to add a grid of identical heatsink fins with a custom shape to a heatsink geometric model.

In a third variant, receiving an edit to the controllable anchor latents S510 can involve transforming the controllable anchor latents using physics-based transforms. Transforming the controllable anchor latents using physics-based transforms can include passing the original anchor points into a physical simulation or modelling software and specifying a deformation. Transforming the controllable anchor latents using physics-based transforms can include passing the original anchor points into a physical simulation or modelling software and specifying a deformation (e.g. determining anchor point transformations if the object was impacted, heated, and/or otherwise affected). The physical modelling software can use material characterization data (e.g., material type, strength, density, melting point, etc.), inputted deformation information (e.g., temperature, force, time etc.), and physics-based mathematics to determine new anchor point positions.

In a fourth variant, receiving an edit to the controllable anchor latents S510 involves modifying the controllable anchor latents using multi-modal inputs. In an example of the fourth variant, receiving an edit to the controllable anchor latents S510 can include passing a text description of a geometry change as input into a machine learning language model (e.g., transformer, LLM, multimodal model, etc.), wherein the model outputs updated anchor point coordinates.

In a fifth variant, receiving an edit to the controllable anchor latents S510 can involve removing controllable anchor latents. Removing controllable anchor latents can include removing the controllable anchor latents and the associated latents, and/or can otherwise be performed. Removing controllable anchor latents preferably does not include repeating all or parts of S300-S400 for the new anchor point set, but can alternatively include sampling a new set of anchor points, regenerating the local geometric latents, regenerating the controllable anchor latents, and/or repeating any other suitable step.

In variants, the edited controllable latents can be further post-processed. In variants, examples of post-processing can include smoothing, filling gaps, removing noise, and/or any other post processing steps. For example, controllable latents can be copied and pasted to fill in gaps. In another example, post-processing can include shifting the controllable latent and/or anchor points fill in gaps. However, post-processing can include any other steps. The post-processing can be performed using machine learning models, algorithms, operations, and/or any other method. However, edits can be in any other suitable format.

However, receiving an edit to the controllable anchor latents S510 may be otherwise configured.

Updating the global representation S530 functions to generate a new global representation for the updated geometry. Updating the global representation S530 can involve using previously determined local geometric latents and/or controllable anchor latents or can involve re-determining geometric and/or controllable anchor latents.

In a first variant, updating the global representation S530 can include repeating S450 using the updated anchor point positions. In this variant of updating the global representation S530, the anchor points retain their prior controllable anchor latents, wherein generating the new global representation can include repeating S450 using the anchor points with the old controllable anchor latents and new anchor point positions. In another example, updating the global representation S530 can include reassigning controllable anchor latents to new positions, and passing them into a model to determine a new global representation (e.g. repeating S450 with updated inputs regarding controllable anchor latent positions).

In a second variant, updating the global representation S530 involves modifying the global representation using the updated anchor points. In this variant, updating the global representation S530 can include the anchor points retaining their prior global latents (e.g., encoding the global representation), wherein the anchor point positions within the global representation are modified to the updated anchor point positions.

In a third variant, updating the global representation S530 can involve determining new controllable anchor latents based on the local geometric latents. Determining new controllable anchor latents based on the local geometric latents can include reassigning previously determined local geometric latents to the edited anchor points, then determining new controllable anchor latents based on the newly-assigned local geometric latents (e.g., repeating S430 using new anchor points). Updating the global representation S530 can include determining a new global representation based on the new controllable anchor latents (e.g., repeating S450 using the new controllable anchor latents).

In a fourth variant, updating the global representation S530 can involve generating new global latents using probabilistic generative models. Generating new global latents using probabilistic generative models can include using a conditional continuous normalizing flow (CNF) to estimate a new global representation. The predictive model can be trained to learn continuous transformations that map probabilistic distributions to some known variable quantities based on CNF. In an example, the predictive model can be trained to update a global representation based on probabilities associated with updates in anchor points and controllable anchor latents. The probabilistic generative models can be flow-based models (e.g., PointFlow, Normalizing Flows, etc.), diffusion models, latent diffusion models, generative adversarial networks, variational autoencoders, and/or any other probabilistic generative models. However, updating the global representation S530 can be performed using any suitable method.

However, updating the global representation S530 may be otherwise configured.

Generating a new final geometry from the updated global representation S550 functions to generate an updated geometric model associated with the updated anchor point set. Generating a new final geometry from the updated global representation S550 can include repeating S470-S490 to generate a new final geometry using the updated global representation, but can alternatively be otherwise performed. However, generating a new final geometry from the updated global representation S550 can be otherwise performed.

However, the generating a new final geometry from the updated global representation S550 may be otherwise configured.

However, updating the final geometry S500 may be otherwise configured.

In variants, the final geometry can be used for 3D rendering. The 3D rendering can be for developing 3D assets for media, simulation software, and/or any other applications. The final geometry can be used for CAD and manufacturing, physics and engineering simulation, and/or and other applications. For example, the final geometry can aid in designing and modelling mechanical parts, be used in physics and engineering simulations (e.g., finite element analysis, computational fluid dynamics, other physical simulations for testing, etc.). In variants, the final geometry and/or simulation results using the final geometry can be used to fabricate a mechanical and/or electrical component.

The method can optionally include training the models S600, which functions to determine and/or learn the weights and/or parameters of the models (e.g., encoders, decoders, etc.) to enable accurate geometric representation and reconstruction. Training the models S600 can be performed after S400, after S500, before S100, or at any suitable time. Training the models S600 can be performed once, iteratively, continuously, periodically, when a novel and/or unique geometry is determined, or at any suitable frequency.

Training the models S600 can include supervised learning (e.g., using ground-truth and/or target geometries, etc.), self-supervised training, unsupervised training (e.g., autoencoding objective, etc.), semi-supervised training, and/or multi-task training (e.g., joint prediction of occupancy, normals, curvature, etc.).

In variants, the methods for training the models S600 can be performed by an encoder-decoder architecture. In an example, the models can include a local geometry encoder, an anchor latent encoder, a global representation encoder, and/or a spatial value decoder. In this variant, the encoders and decoders can be trained together end-to-end. In another variant, subsets of the models can be trained together. In other variants, the models can be trained individually. In an example, the local geometry encoder can be trained independently (e.g., as an autoencoder of local fields). In another example, the anchor latent encoder can be trained individually on frozen local geometric latents. In this example, the global representation model can be trained after anchor latent stabilization. In variants, the method can include pre-training of components. For example, training the models S600 can include training the full pipeline end-to-end after component pre-training. However, the models can additionally and/or alternatively be otherwise trained.

The training data can include a dataset of geometric representations and corresponding ground-truth geometries as the training target (e.g., meshes, point clouds, voxel grids, SDF fields, occupancy grids, CAD models, etc.). The training data can include synthetic data (e.g., procedurally generated geometries), simulated data, real-world scanned data, manually designed geometries, and/or any other data. In variants, the models can be trained as an autoencoder, such that the training data and training target can be the same data.

In variants, the training data can include multi-resolution representations of the same geometry. In an example, a set of training data can include a lower resolution representation while the training target is a higher resolution representation.

In variants, training the models S600 can include training the system using a plurality of geometries. In variants, the geometries can be of varying length scales, have unique features, have different industry applications, have a variety of feature length scales, and/or have any other traits. For example, the models can be trained using geometries with features that are nanoscale, microscale, mesoscale, macroscale, and/or any other length scales. The inventors have found that using a wide variety of geometries can result in more accurate predictions and consistent performance.

In variants, training the models S600 can include computing a loss between the final output and the training target. The losses can include data losses, gradient losses, regularization losses, contrastive losses, metric learning losses, adversarial losses, and/or any other losses. Training the models S600 can use physics-informed losses, and/or any other suitable losses. Examples of losses can include occupancy loss (e.g., binary cross-entropy between predicted and ground-truth occupancy), signed distance loss (e.g., L1, L2 loss between predicted and ground-truth SDF values), Chamfer distance between predicted and ground-truth point clouds, earth mover's distance (EMD), mesh-based losses (e.g., vertex-to-vertex distance, edge length regularization), and/or any other losses. In some variants, training the models S600 can include computing regularization losses. Examples of regularization losses can include smoothness regularization (e.g., gradient penalty on SDF), surface normal consistency loss, curvature regularization, Laplacian regularization on meshes, sparsity constraints on latent vectors, and/or any other regularization losses. However, training the models S600 can include computing any suitable losses.

Training the models S600 can include performing gradient-based optimization, stochastic gradient descent, Adam optimization, RMSProp optimization, and/or any other optimization technique.

However, training the models S600 may be otherwise configured.

### 4. System

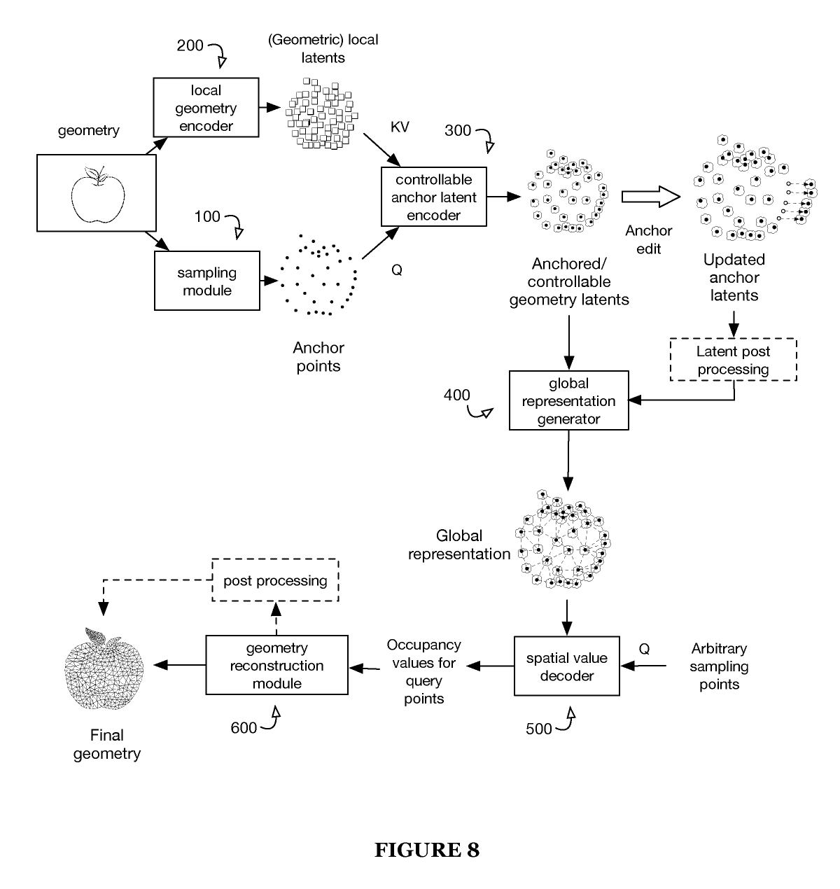

As shown for example in FIG. 8, variants of the system can include a sampling module 100; a local geometry encoder 200; a controllable anchor latent encoder 300; a global representation generator 400; a spatial value decoder 500; a geometry reconstruction module 600; and a user interface 700. The system functions to determine an editable geometry based on an object representation. In variants, the system can include a computing system, computer, processor, memory, storage, and/or any other suitable components. The system memory and/or database can include a set of modules, models, algorithms, and/or any other suitable component for executing the method described above. The models and/or modules can include statistical models, empirical models, mathematical models, machine learning models, and/or any other suitable models.

Machine learning models can include input layers and/or input heads. The machine learning models can include dense (e.g., fully connected, linear, etc.) layers, convolutional layers, attention layers (e.g. cross attention, sliced attention, self-attention, multi-head attention, global attention, local attention, etc.), transformer blocks, recurrent layers, residual blocks, normalization layers (e.g., batch normalization, layer normalization, group normalization, instance normalization, etc.), pooling layers (e.g., max pooling, average pooling, etc.), dropout layers, activation functions. and/or any other components.

The sampling module 100 functions to determine a set of points (e.g., anchor points). The sampling module 100 can determine a set of points and/or a point cloud of a geometry and/or design. The sampling module 100 can receive a geometric representation, a design, a physical object, an image or set of images, CAD file, and/or any other suitable representation of a geometry. The geometric representation can be discrete, continuous, or be otherwise represented. Examples of a geometric representation can include a point cloud, mesh, voxel data, implicit surface data, parametric representation, and/or any other geometric representation.

In a first variant, the sampling module 100 can determine points by sampling the geometry. The sampling can include uniform sampling, adaptively sampling, multi-resolution sampling, sampling based on a geometric or design property (e.g., curvature, density, surface normals, error metrics, reconstruction uncertainty, distance from a reference location, learned feature importance, etc.), probabilistic sampling, edge sampling, importance sampling, stratified sampling, Poisson sampling, grid sampling, farthest point sampling, blue-noise sampling, Markov chain Monte Carlo sampling, rejection sampling, low-discrepancy sequence sampling, quasi-random sampling, random sampling, sampling based on a ruleset, and/or any other method.

In a second variant in which the geometry is a physical object, the set of points can be determined through measuring. The sampling module 100 can include a laser scanner, LiDAR, structured light scanner, time-of-flight camera, photogrammetry camera system, stereo camera, probe arm, coordinate measuring machine, and/or any other suitable measuring device. In an example, a set of points can be determined by measuring a physical geometry using at least one of the measurement devices.

In a third variant, the sampling module 100 can include a machine learning model (e.g., neural network, convolutional neural network, recurrent neural network, deep neural network, transformer, and/or any other machine learning model). In an example, the machine learning model can receive as input a geometric representation, and determine a set of anchor points based on the geometric representation.

In a fourth variant, the sampling module 100 can include a set of rules, policy, and/or heuristics. The set of points can be determined based on the rules, heuristics, and/or policies. The rules, heuristics, and/or policies can be handcrafted, manually determined, learned, and/or otherwise determined. In variants, the anchor points determined from the sampling module 100 can act as control points.

However, the sampling module 100 may be otherwise configured.

The local geometry encoder 200 functions to determine local geometric latents and/or embeddings based on the geometry. The local geometry encoder 200 preferably receives a geometric representation, but can alternatively receive any other suitable input. The local geometry latents can include a latent vector, scalar, tensor, tensor, feature map, and/or any other suitable data representation. In a specific variant, the local geometry latents can include geometry-aware local adaptive (GALA) nodes. The local geometry encoder 200 can determine a set of local geometric latents and/or embeddings that represent the geometry at a specific location and/or position (e.g., spatial patches, local geometry). The local geometric latents can be treated as a key-value structure, wherein the location of the node is a key and the local geometric latents are values.

In a first variant, the local geometry encoder 200 can include machine learning models. The machine learning models can include neural networks, multi-layer perception models, convolutional neural networks, graph neural networks, deep neural networks, transformers, and/or any other suitable models. In variants, the machine learning model can include an attention mechanism (e.g., self-attention, cross-attention, sliced attention, etc.). In an example of the first variant, a mesh and/or point cloud can be passed as input to a machine learning model to determine a set of local geometric latents and/or embeddings (e.g., that represent the geometric information in a latent feature space).

In a second variant, the local geometry encoder 200 can include mathematical transformations (e.g., that represent the geometric representation in a different basis). Examples of transformation can include frequency-based transforms, spectral-based transform, scale-based transform, eigenfunction-based transforms, statistical transforms, Fourier transform, Laplace-Beltrami eigenbasis, graph Fourier transform, wavelet transform, basis expansion (e.g., spherical harmonics, radial basis function, polynomial, etc.) principal component analysis, modal decomposition, neural transforms, and/or any other suitable transformation.

In a third variant, the local geometry encoder 200 can include computing a field based on the geometry. Examples of field-based representations can include signed distance function, unsigned distance function, occupancy field, normal field, curvature field, and/or any other geometric field.

In a third variant, the local geometry encoder 200 can include a combination of the variants. In an example, the local geometry encoder 200 can first include computing a field-based representation and performing a numerical and/or basis transform of the field-based representation. In a second example, the local geometry encoder 200 can include performing a numerical transform of the geometric representation and encoding the transformed data using a machine learning model. In an example, the local geometry encoder 200 can include computing a signed distance function of the geometry and then performing a spectral-based transform, such as a Laplace–Beltrami eigenbasis transform, on the signed distance function to determine local geometric latents. In an example, the local geometry encoder 200 can include computing a curvature field (e.g., mean curvature or Gaussian curvature) of a mesh and performing a wavelet transform on the curvature field, which are then encoded as geometric embeddings using a machine learning model.

In some variants, the local geometry encoder 200 can encode the local geometric latents in hierarchical data structures (e.g. Octree, Quadtree, B-tree, k-d tree, R-tree, etc.). In variants, the geometric features with a smaller lengthscale can be encoded separately and/or differently from geometric features of larger lengthscale. In examples, the local geometry encoder 200 can include: a local coordinate system (e.g., geometry-aware local adaptive grid (GALA) model, PointNet, Frame Fields, SplineCNN, etc.), spectral embeddings (e.g., ShapeNet, MeshCNN, graph Laplacians, etc.), geodesic-based embeddings (e.g., geodesic CNNs, heat kernel signatures, etc.), and/or any other architectures.

However, the local geometry encoder 200 may be otherwise configured.

The controllable anchor latent encoder 300 functions to determine controllable anchor latents based on the local geometry latents. The controllable anchor latent encoder 300 preferably receives local geometric latents and/or embeddings from the local geometry encoder, but can receive any other input. The controllable anchor latents can include a latent vector, scalar, tensor, feature map, and/or any other suitable data representation. The controllable anchor latents can be treated as a key-value structure, wherein the location of the node is a key and the controllable anchor latents are values.

In a first variant, the controllable anchor latent encoder 300 can include machine learning models (e.g., neural networks, graph neural networks, transformers, recurrent networks, and/or any other network). In an example, a set of local geometric latents can be passed as input through the model to determine a set of controllable anchor latents. In variants, the machine learning model can include an attention mechanism (e.g., self-attention, cross-attention, sliced attention, etc.). The attention mechanism can ensure the controllable anchor latents that describe the relationships between local geometry latents.

In a second variant, the controllable anchor latent encoder 300 can include aggregation operations such as averaging, summing, pooling, attention-based aggregation, concatenation, and/or any other operations. In an example, a set of local geometric latents can be aggregated using an aggregation operation.

In variants, the controllable anchor latents can include positional embeddings and/or any positional information (e.g., based on anchor points determined using the sampling module, etc.). In variants, the controllable anchor latent encoder 300 determines controllable anchor latents based on a cluster of local geometry latents. Clusters and/or subsets of local geometry latents can be determined using a clustering module 350.

In variants, the controllable anchor latent encoder 300 can include an optional clustering module 350, which functions to determine clusters of local geometric latents for determining a controllable anchor latent. The clustering module 350 can group local geometric latents based on spatial proximity, based on similarity in latent feature space, randomly, based on learned policy, rules, and/or heuristics, randomly, or in any suitable manner. In variants, wherein clustering is determined based on learned policy or rules, the policies and rules can be determined based on downstream task performance, reconstruction error, and/or any other suitable metrics. The clustering module 350 can determine clusters iteratively, once, or in any other suitable manner.

In a variant, the clustering module 350 can assign every local geometric latent (e.g., determined by the local geometry encoder) to an anchor point (e.g., determined by the sampling module). The clustering module 350 can include clustering methods such as k-means, hierarchical clustering, DBSCAN, mean shift, spectral clustering, Gaussian mixture models, and/or any other suitable clustering method. In variants, the clustering module 350 can incorporate learned clustering using neural network-based approaches, attention mechanisms, or graph-based aggregation.

In variants, the clustering module 350 can compute distance metrics. The distance metrics can include Euclidean, cosine similarity, Mahalanobis distance, learned similarity metrics, and/or any other suitable distance. For example, in variants in which clusters are determined based off spatial proximity, the clustering module 350 can determine the distance between the position of every local geometric latent and every anchor point. Every local geometric latent can be assigned to an anchor point that it is closest to. However, clusters can be otherwise determined.

In variants, the clustering module 350 can assign weights or importance scores to local geometry latents within each cluster. The weights can be determined based on spatial proximity, heuristics, learned policy, an importance metric, and/or any other suitable method. In an example, local geometry latents that are closer to the anchor point can have a higher weight. In an example, local geometry latents that are associated with specific geometric features can have a higher weight. The weights can be passed with the local geometry latents into the controllable anchor latent encoder. However, the weights can additionally and/or alternatively be otherwise utilized. The clustering module 350 can generate non-overlapping clusters, overlapping clusters, hierarchical clusters, or any other suitable clusters.

In a first variant, every local geometric latent is assigned to one anchor point. In a second variant, a local geometric latent can be assigned to a plurality of anchor points (e.g., based on a threshold spatial proximity, soft assignment, etc.). In a third variant, local geometric latents are assigned to anchor points but are weighted (e.g., by its proximity and/or any other weighting factor).

In variants, the controllable anchor latent encoder 300 can encode controllable anchor latents associated with geometric features with a smaller lengthscale separately and/or differently from controllable anchor latents associated with geometric features of larger lengthscale. For example, each controllable anchor latent can be associated with lengthscale-related encodings and/or weights.

However, the clustering module 350 may be otherwise configured.

However, the controllable anchor latent encoder 300 may be otherwise configured.

The global representation generator 400 functions to determine a global representation based on the controllable anchor latents. The global representation generator 400 preferably receives controllable anchor latents determined by the controllable latent encoder, but can alternatively receive local geometric latents, and/or any other suitable data. The global representation generator 400 can generate a global representation. The global representation can include a latent vector, tensor, feature map, and/or any other suitable data representation. The global representation can be in a latent feature space, embedding space, and/or any other space. The global representation generator 400 can include a machine learning model (e.g., neural network, multi-layer perception model, convolutional neural network, graph neural network, deep neural network, transformer, etc.). In variants, the machine learning model can include an attention mechanism (e.g., self-attention, cross-attention, sliced attention, etc.). The attention mechanism can ensure the global representation includes embeddings that describe the relationships between controllable anchor latents. For example, the set of controllable anchor latents can be passed as input to a machine learning model. The machine learning model can output a tensor, matrix, and/or any other representation that represents the connection and/or relationship between features of the geometry. The global representation can include a set of global latents that describe and/or encode the controllable anchor latent relationships. In other variants, the global representation generator 400 can include aggregation operations such as concatenation, summing, averaging, and/or any other operation.

However, the global representation generator 400 may be otherwise configured.

The spatial value decoder 500 functions to determine spatial values based on the global representation. The spatial value decoder 500 can receive the global representation (e.g., determined from the global representation generator) and/or any other suitable data. In variants, the spatial value decoder 500 can receive a set of query points. In an example, the spatial value decoder 500 can determine spatial values for the set of query points based on the global representation. The query points can include user-specified points, grid points based on a desired resolution, and/or any other points. The spatial value decoder 500 can determine occupancy values, density, signed distance function, normals, curvature values, occupancy probability, neural representations, wavelet fields, O-voxel parameters, and/or any spatial field representation of a geometry. The spatial value decoder 500 can include machine learning models such as neural networks, multi-layer perceptron, graph neural networks, convolutional neural networks, transformers, recurrent neural networks, natural language processing models (e.g., Seq2seq, etc.), state space models (e.g., Mamba models, etc.), hybrid architectures, and/or any other suitable model. In variants, the machine learning model can include an attention mechanism (e.g., self-attention, cross-attention, sliced attention, etc.). In another variant, the spatial value decoder 500 can include a look-up mechanism that can retrieve spatial values based on the geometric representation. In variants, the local geometry encoder, controllable latent encoder, global representation generator, and spatial value decoder 500 can be trained end-to-end as a single model architecture. In another variant, subsets of the components can be trained together. However, the models can additionally and/or alternatively be otherwise trained.

However, the spatial value decoder 500 may be otherwise configured.

The geometry reconstruction module 600 functions to determine a final geometry based on the spatial values. The geometry reconstruction module 600 can receive spatial values (e.g., determined from the spatial value decoder) and/or any other suitable input.

The geometry reconstruction module 600 can include algorithms and/or operations such as marching cubes, dual contouring, Poisson surface reconstruction, Delaunay-based meshing, alpha shapes, advanced front meshing, grid-based surface extraction, surface net algorithms, implicit function thresholding, contour extraction, hybrid methods, and/or any other algorithms and/or operations. In a variant, the geometry reconstruction module 600 can produce a final geometric representation based on the spatial values determined by the spatial value decoder. The final geometric representation can include a point cloud, mesh, voxel data, implicit surface data, parametric representation, and/or any other geometric representation.

In variants, the geometry reconstruction module 600 can include post-processing algorithms for smoothing, filling holes, enforce continuity, refining topology, mesh simplification, edge sharpening, noise removal, and/or any other functions. The geometry reconstruction module can include Laplacian smoothing, Taubin smoothing, bilateral surface filtering, curvature based interpolation, constrained patch filling, vertex clustering, edge collapse, curvature-based sharpening, edge enhancement, statistical outlier removal, median filtering, machine-learning based post processing (e.g., based on learned policy, etc.), and/or any other geometry reconstruction module components.

However, the geometry reconstruction module 600 may be otherwise configured.

The user interface 700 functions to enable a user to interact with the platform and display visuals of the geometry of interest. The user interface 700 can allow a user to upload a geometry and/or geometric representation for processing (e.g., a CAD file, a point cloud, an image, a set of images, a mesh file, and/or any other files). The user interface 700 can be interacted with by the user via mouse and/or cursor movements, clicks, voice control, prompts, natural language, and/or any other methods. The user interface 700 can allow a user to specify parameters of the modules (e.g., for determining latents, anchor points, etc.). The user interface 700 can allow a user to specify parameters of the modules (e.g., for determining latents, anchor points, etc.). For example, a user can specify a sampling method of the sampling module, a clustering method of the clustering module, hyperparameters of the models, and/or any other settings. The user interface 700 can allow a user to input query points (e.g., for the spatial value decoder) and/or any other inputs. The user interface 700 can present visualizations of the geometry, the sampled points, the controllable anchor latents, the final reconstructed geometry, and/or any other suitable visuals. The user interface 700 can notify when a final geometry is reconstructed, an estimated time for reconstructing a geometry, and/or any other information.

In variants, the user interface 700 includes a geometry editor 750.

The geometry editor 750 functions to enable a user to edit a geometry. The geometry editor 750 can allow a user to drag, re-position, delete, copy-and-paste, and/or otherwise edit the controllable anchor latents. In some variants, the geometry editor 750 can receive natural language prompts. For example, a user can provide the geometry editor 750 a prompt describing a change in the geometry. The geometry editor 750 can include a machine learning model (e.g., large language model) that can perform a change in the geometry, anchor points, and/or controllable anchor latents based on the prompt. In some variants, the geometry editor 750 can edit the controllable anchor latents algorithmically, using machine learning models and/or agents, using reinforcement learning models, using physics-based simulators, and/or any other method.

In variants, in which edits are made using reinforcement learning models, an agent can make edits to the controllable anchor latents and be rewarded (e.g., reinforcement learning) based on some objective in order to learn policies related to geometric edits. Examples of policies can be based on the predicted functionality of the edited geometry, the appearance of the edited geometry, the physical plausibility of the edited geometry, and/or any other basis.

In variants, the geometry editor 750 can allow users to edit local geometric latents or controllable anchor latents (e.g., adjusting feature weights, clustering method, etc.). In variants, the geometry editor 750 can include machine learning models and/or other modules that can perform post processing on the edited controllable anchor latents. For example, the machine learning models can smooth, fill, remove noise, and/or otherwise process the edited controllable anchor latents.

However, the geometry editor 750 may be otherwise configured.

However, the user interface 700 may be otherwise configured.

### 5. Specific Examples

Specific Example 1. A method comprising: determining a set of anchor points of an initial geometry; encoding a set of spatial patches of the intital geometry as a set of local geometric latents; assigning the set of local geometric latents to the set of anchor points to determine clusters of local geometric latents, wherein each cluster comprises a subset of the set local geometric latents; encoding each cluster of local geometric latents as a set of anchor latents; determining a global representation based on the set of anchor latents, wherein the global representation comprises a contextualized embedding set defining relationships between each of the set of anchor latent; determining a set of query points; determining a set of spatial values based on the query points and the global representation using a decoder; and determining a final geometry based on the set of spatial values.

Specific Example 2. The method of Specific Example 1, wherein determining the global representation comprises applying a self-attention operation across the set of anchor latents.

Specific Example 3. The method of Specific Example 1, wherein each spatial patch of the set comprises a local geometric field representation of the geometry, wherein encoding the set of spatial patches comprises performing a wavelet transform on the local geometric field representations.

Specific Example 4. The method of Specific Example 1, wherein assigning the set of local geometric latents comprises for each local geometric latent, determining distances between the local geometric latent and the set of anchor points, wherein each local geometric latent is assigned to a closest anchor point.

Specific Example 5. The method of Specific Example 1, wherein determining the set of anchor points comprises adaptively sampling the initial geometry.

Specific Example 6. The method of Specific Example 5, wherein adaptively sampling the geometry comprises sampling the initial geometry based on local curvatures of the geometry.

Specific Example 7. The method of Specific Example 1, wherein the set of spatial values comprises occupancy values.

Specific Example 8. The method of Specific Example 1, further comprising, after determining a global representation: determining a set of updated anchor latents based on the set of anchor latents, comprising determining at least one updated spatial position for at least one anchor point associated with an anchor latent; determining an updated global representation based on the updated anchor latents; and determining an updated final geometry based on the updated global representation.

Specific Example 9. The method of Specific Example 8, wherein determining an updated spatial position of the anchor point comprises, on a user interface, dragging the anchor point to a new position.

Specific Example 10. The method of Specific Example 8, wherein determining a set of updated anchor latents further comprises duplicating at least one of the anchor latents.

Specific Example 11. The method of Specific Example 1, wherein the set of query points comprises a higher resolution than the set of anchor points.

Specific Example 12. A system comprising: a sampling module that determines a set of anchor points of an initial geometry; a local geometry encoder that: determines a set of spatial patches of the geometry; and determines a set of local geometric latents comprising, for each spatial patch, encoding geometric information associated with the spatial patch; a controllable anchor latent encoder that determines a set of controllable anchor latents comprising, for each controllable anchor latent, encoding a subset of the set of local geometric latents; a global representation generator that determines a contextualized embedding set based on the set of anchor latents comprising encoding inter-anchor relationships between anchor latents of the set of anchor latents; a decoder that determines a set of spatial values based on a set of query points and the global representation; and a geometry reconstruction module that determines a final geometry based on the set of spatial values.

Specific Example 13. The system of Specific Example 12, wherein the global representation generator comprises a set of self-attention layers.

Specific Example 14. The system of Specific Example 12, wherein the subset of local geometric latents is determined by clustering the set of local geometric latents based on distance to a closest anchor point of the set of anchor points.

Specific Example 15. The system of Specific Example 12, wherein the set of spatial values comprises signed distance values.

Specific Example 16. The system of Specific Example 12 wherein: the global representation generator further determines an updated global representation based on a set of updated anchor latents, wherein the set of updated anchor latents is based on the set of anchor latents; and the geometry reconstruction module further determines an updated final geometry based on the updated global representation.

Specific Example 17. The system of Specific Example 16, wherein determining the set of updated anchor latents comprises determining a set of updated spatial positions of the anchor points associated with the set of anchor latents.

Specific Example 18. The system of Specific Example 16, wherein the updated spatial positions are determined using a physics-based simulator

Specific Example 19. The system of Specific Example 16, wherein determining the updated global representation comprises determining a new contextualized embedding set based on the updated spatial positions of the anchor points.

Specific Example 20. The system of Specific Example 12, wherein the final geometry comprises a higher resolution than the initial geometry.

All references cited herein are incorporated by reference in their entirety, except to the extent that the incorporated material is inconsistent with the express disclosure herein, in which case the language in this disclosure controls.

As used herein, "substantially" or other words of approximation can be within a predetermined error threshold or tolerance of a metric, component, or other reference, and/or be otherwise interpreted.

Optional elements, which can be included in some variants but not others, are indicated in broken line in the figures. However, unbroken lines in the figures should not be interpreted to indicate that the depicted elements are essential, nor to indicate that the depicted elements may not be omitted from variants of the invention.

Different subsystems and/or modules discussed above can be operated and controlled by the same or different entities. In the latter variants, different subsystems can communicate via: APIs (e.g., using API requests and responses, API keys, etc.), requests, and/or other communication channels. Communications between systems can be encrypted (e.g., using symmetric or asymmetric keys), signed, and/or otherwise authenticated or authorized.

Alternative embodiments implement the above methods and/or processing modules in non-transitory computer-readable media, storing computer-readable instructions that, when executed by a processing system, cause the processing system to perform the method(s) discussed herein. The instructions can be executed by computer-executable components integrated with the computer-readable medium and/or processing system. The computer-readable medium may include any suitable computer readable media such as RAMs, ROMs, flash memory, EEPROMs, optical devices (CD or DVD), hard drives, floppy drives, non-transitory computer readable media, or any suitable device. The computer-executable component can include a computing system and/or processing system (e.g., including one or more collocated or distributed, remote or local processors) connected to the non-transitory computer-readable medium, such as CPUs, GPUs, TPUS, microprocessors, or ASICs, but the instructions can alternatively or additionally be executed by any suitable dedicated hardware device.

Embodiments of the system and/or method can include every combination and permutation of the various system components and the various method processes, wherein one or more instances of the method and/or processes described herein can be performed asynchronously (e.g., sequentially), contemporaneously (e.g., concurrently, in parallel, etc.), or in any other suitable order by and/or using one or more instances of the systems, elements, and/or entities described herein. Components and/or processes of the following system and/or method can be used with, in addition to, in lieu of, or otherwise integrated with all or a portion of the systems and/or methods disclosed in the applications mentioned above, each of which are incorporated in their entirety by this reference.

As a person skilled in the art will recognize from the previous detailed description and from the figures and claims, modifications and changes can be made to the preferred embodiments of the invention without departing from the scope of this invention defined in the following claims.

We claim:

1. A method comprising:
determining a set of anchor points of an initial geometry;
encoding a set of spatial patches of the intital geometry as a set of local geometric latents;
assigning the set of local geometric latents to the set of anchor points to determine clusters of local geometric latents, wherein each cluster comprises a subset of the set local geometric latents;
encoding each cluster of local geometric latents as a set of anchor latents;
determining a global representation based on the set of anchor latents, wherein the global representation comprises a contextualized embedding set defining relationships between each of the set of anchor latent;
determining a set of query points;
determining a set of spatial values based on the query points and the global representation using a decoder; and
determining a final geometry based on the set of spatial values.

2. The method of claim 1, wherein determining the global representation comprises applying a self-attention operation across the set of anchor latents.

3. The method of claim 1, wherein each spatial patch of the set comprises a local geometric field representation of the geometry, wherein encoding the set of spatial patches comprises performing a wavelet transform on the local geometric field representations.

4. The method of claim 1, wherein assigning the set of local geometric latents comprises for each local geometric latent, determining distances between the local geometric latent and the set of anchor points, wherein each local geometric latent is assigned to a closest anchor point.

5. The method of claim 1, wherein determining the set of anchor points comprises adaptively sampling the initial geometry.

6. The method of claim 5, wherein adaptively sampling the geometry comprises sampling the initial geometry based on local curvatures of the geometry.

7. The method of claim 1, wherein the set of spatial values comprises occupancy values.

8. The method of claim 1, further comprising, after determining a global representation:
determining a set of updated anchor latents based on the set of anchor latents, comprising determining at least one updated spatial position for at least one anchor point associated with an anchor latent;
determining an updated global representation based on the updated anchor latents; and

9. The method of claim 8, wherein determining an updated spatial position of the anchor point comprises, on a user interface, dragging the anchor point to a new position.

10. The method of claim 8, wherein determining a set of updated anchor latents further comprises duplicating at least one of the anchor latents.

11. The method of claim 1, wherein the set of query points comprises a higher resolution than the set of anchor points.

12. A system comprising:
a sampling module that determines a set of anchor points of an initial geometry;
a local geometry encoder that:
determines a set of spatial patches of the geometry; and
determines a set of local geometric latents comprising, for each spatial patch, encoding geometric information associated with the spatial patch;
a controllable anchor latent encoder that determines a set of controllable anchor latents comprising, for each controllable anchor latent, encoding a subset of the set of local geometric latents;
a decoder that determines a set of spatial values based on a set of query points and the global representation; and
a geometry reconstruction module that determines a final geometry based on the set of spatial values.

13. The system of claim 12, wherein the global representation generator comprises a set of self-attention layers.

14. The system of claim 12, wherein the subset of local geometric latents is determined by clustering the set of local geometric latents based on distance to a closest anchor point of the set of anchor points.

15. The system of claim 12, wherein the set of spatial values comprises signed distance values.

16. The system of claim 12 wherein:
the global representation generator further determines an updated global representation based on a set of updated anchor latents, wherein the set of updated anchor latents is based on the set of anchor latents; and

17. The system of claim 16, wherein determining the set of updated anchor latents comprises determining a set of updated spatial positions of the anchor points associated with the set of anchor latents.

18. The system of claim 16, wherein the updated spatial positions are determined using a physics-based simulator.

19. The system of claim 16, wherein determining the updated global representation comprises determining a new contextualized embedding set based on the updated spatial positions of the anchor points.

20. The system of claim 12, wherein the final geometry comprises a higher resolution than the initial geometry.
